(19) United States
(12) Patent Application Publication
(10) Pub. No.: US 2023/0161559 A1
(43) Pub. Date: May 25, 2023

(54) TECHNOLOGY TO REALIZE SIGNED MULTIPLY-ACCUMULATE OPERATION IN THE ANALOG DOMAIN WITH A DIFFERENTIAL SIGNAL PATH AND INTRINSIC PROCESS, VOLTAGE AND TEMPERATURE VARIATION TOLERANCE

(71) Applicant: Intel Corporation, Santa Clara, CA (US)

(72) Inventors: Hechen Wang, Portland, OR (US); Renzhi Liu, Portland, OR (US); Richard Dorrance, Hillsboro, OR (US); Deepak Dasalukunte, Beaverton, OR (US); Brent Carlton, Portland, OR (US)

(21) Appl. No.: 18/159,220

(22) Filed: Jan. 25, 2023

(51) Int. Cl. G06F 7/544; G06F 7/48; H03M 1/78; H03M 1/46

(52) U.S. Cl. CPC G06F 7/5443; G06F 7/4824; H03M 1/78; H03M 1/462

(57) ABSTRACT

Systems, apparatuses and methods may provide for technology that conducts, by a differential signal path, signed multiply-accumulate (MAC) operations on first analog signals and multibit weight data stored in the differential signal path, and outputs, by the differential signal path, second analog signals based on the signed MAC operations.

### TECHNICAL FIELD

Embodiments generally relate to artificial intelligence (AI) computing. More particularly, embodiments relate to technology to realize signed multiply-accumulate (MAC) operation in the analog domain with a differential signal path and intrinsic process, voltage, and temperature (PVT) variation tolerance.

### BACKGROUND OF THE DISCLOSURE

Compute-in-memory (CiM) static random-access memory (SRAM) architectures may deliver increased efficiency to convolutional neural network (CNN) models. A notable trend in CiM processor architectures may be to use analog mixed-signal (AMS) hardware when performing multiply-accumulate (MAC) operations in a CNN model. Most AMS CiM processors, however, have relatively low process, voltage, and temperature (PVT) variation tolerance. Additionally, AMS CiM processors may have increased memory requirements depending on the input data format.

### BRIEF DESCRIPTION OF THE DRAWINGS

The various advantages of the embodiments will become apparent to one skilled in the art by reading the following specification and appended claims, and by referencing the following drawings, in which:

FIG. 1 is an illustration of an example of a remapping of data;

FIGS. 2A-2C are plots of examples of error profiles for unsigned data, code remapped to signed magnitude format, and code remapped to 2's complement format, respectively;

FIG. 3A is a comparative illustration of an example of a conventional single-ended signal path and corresponding voltage output, and an enhanced differential signal path and corresponding voltage output according to an embodiment;

FIG. 3B is a comparative plot of error profiles for a conventional single-ended signal path and an enhanced differential signal path according to an embodiment;

FIG. 3C is a block diagram of an example of a differential signal path according to an embodiment;

FIG. 4 is a plot of an example of an enhanced voltage output according to an embodiment;

FIG. 5 is a comparative plot of an example of a conventional noise and process, voltage, and temperature (PVT) variability tolerance and an enhanced noise and PVT variability tolerance according to an embodiment;

FIG. 6A is a schematic diagram of an example of a differential capacitor ladder network structure according to an embodiment;

FIG. 6B is a schematic diagram of an example of butterfly switch circuitry and corresponding input data format and output signal format according to an embodiment;

FIG. 7 is a set of charts of examples of weight value distributions according to embodiments;

FIGS. 8A-8C are plots of examples of error profiles for unsigned data, code remapped to 2's complement format, and data in signed magnitude format without remapping according to an embodiment, respectively;

FIG. 9A is a schematic diagram of an example of a current steering digital to analog converter (DAC) according to an embodiment;

FIG. 9B is a schematic diagram of an example of a differential resistive DAC according to an embodiment;

FIG. 10 is a schematic diagram of an example of a differential successive approximation register (SAR) analog to digital converter (ADC) according to an embodiment;

FIG. 11 is a flowchart of an example of a method of operating a compute-in-memory (CiM) processor according to an embodiment;

FIG. 12 is a flowchart of an example of a method of operating a differential signal path according to an embodiment

FIG. 13 is a block diagram of an example of a performance-enhanced computing system according to an embodiment; and

FIG. 14 is an illustration of an example of a semiconductor package apparatus according to an embodiment.

### DETAILED DESCRIPTION

As already noted, analog mixed-signal (AMS) compute-in-memory (CiM) processors may have increased memory requirements depending on the input data format and/or relatively low process, voltage, and temperature (PVT) variation tolerance. For example, most AMS CiM processors have two main challenges: 1) support for signed multi-bit data and 2) PVT variation tolerance.

Signed data format is advantageous in many machine learning (ML) and neural network (NN) applications (e.g., a mixture of positive and negative weight values may be helpful in identifying edges in images). Signed data format may be relatively straightforward in the digital domain because the overhead to support signed formats in digital is merely reserving a single bit, the sign bit, to represent the polarity of the data (e.g., the value “0” represents positive numbers, and the value “1” represents negative numbers). One extra bit of overhead can easily be ignored compared to the remaining 7, 15, 31 or 63 bits. The situation is quite different, however, in the analog domain, since the sign bit is also treated as the most-significant-bit (MSB) of the data, which results in doubling the required operations and normally leading to a doubled memory cell number.

AMS hardware output is also susceptible to PVT variations, limiting the computing precision and, ultimately, the inference accuracy of a CNN model. Computing at the edge also has substantial constraints such as, for example, power limitations (e.g., most edge device, such as wireless sensors, mobile devices, etc., only have a very limited power budget). Thus, intensive operations can drain the battery or the source quickly.

To save power, the most practical and straightforward solution may be lowering the supply voltage of the circuit. The equation of the dynamic power consumption is given by: P=CV²f, where P is the power consumption, C is the loading capacitance of the circuit, V is the supply voltage, and f is the operating frequency. As shown in the equation, the power consumption is proportional to the square of the supply voltage. With a lower supply voltage, hardware and circuits are more sensitive to noise and have larger delay, which will cause error during computation and lead to failure in the classification.

As the PVT variation is a significant issue of AMS MAC implementations, calibration solutions are typically used to guarantee a robust operation and an acceptable computing result. The hardware and power of those variation compensation approaches could be acceptable for low-end precision reduced AMS CNN processors, due to the relaxed SNR requirement. For high precision processors, however, calibration overhead could negate the benefits gained by the AMS implementation.

There are two commonly used low cost methods to achieve signed data format in analog CiM for NN applications: 1) reducing number of bits to only supporting binary (0, 1) or ternary (−1, 0, +1) format, and 2) using unsigned hardware with code remapping. Binary/ternary NN hardware has become very popular in recent years. Especially in CiM implementations, a substantial number of recently reported CiMs are binary or ternary based, as such CiM implementations can demonstrate the highest throughput and power efficiency. Although binary/ternary neural networks have shown high power efficiency, performance and supported applications are severely limited by one-bit data. With only one meaningful bit, this kind of hardware implementation can only deal with some very basic datasets, such as MNIST (Modified National Institute of Standards and Technology database, or CIFAR-10 (Canadian Institute for Advanced Research-Ten database). The accuracy drop may be unacceptable when classifying more complicated datasets, such as CIFAR-100, or ImageNet.

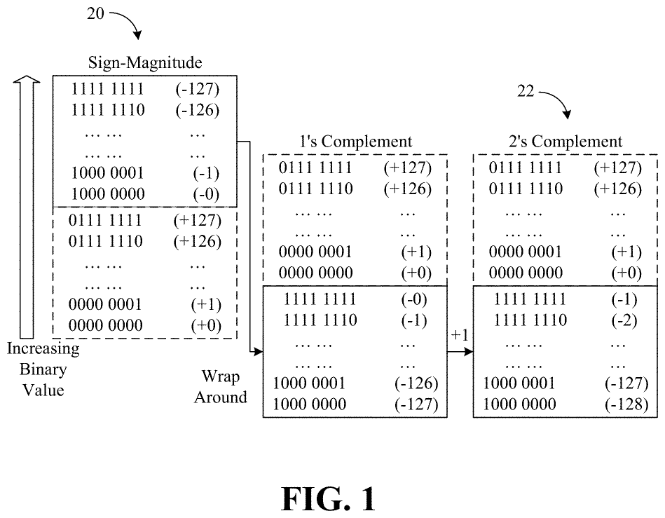

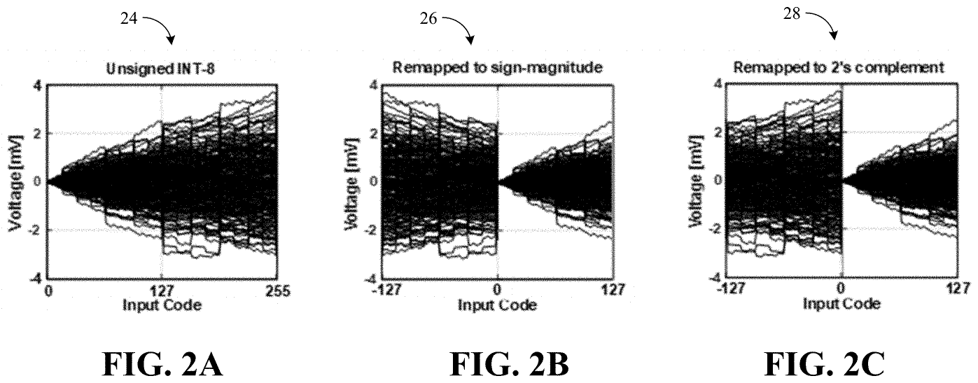

With continuing reference to FIGS. 1 and 2A-2C, if multibit signed format is required, the most commonly adopted solution is data remapping, which rearranges unsigned data, for instance in an 8-bit scenario (0 to 255), to either sign-magnitude format 20 (−127 to +127) or 2's complement format 22 (−128 to +127). The remapped formats 20, 22, however, normally suffer from an error unalignment. As best shown in a plot 24 of FIG. 2A, errors occur during analog operations, and the distribution expands over the input code. In a practical NN, most of the weights and the inputs are small numbers close to zero. FIGS. 2B and 2C demonstrate that with data remapping, half of the data (e.g., negative data) will suffer from larger analog errors as shown in plots 26, 28 for the remapped sign-magnitude format 20 and the remapped 2's complement format 22, respectively.

Digital computing is robust because of sufficient design redundancy. Analog computing, on the other hand, sacrifices the extra robustness for higher power efficiency. Consequently, analog computing typically suffers from the impact of PVT variations and hardware mismatch. One approach to mitigate those negative effects may be to directly lower the supply voltage and accept the resulting errors. Although neural networks, such as especially deep neural networks (e.g., “ResNet”) may be robust to errors, when choosing to accept errors, designers normally need to face a trade-off dilemma: 1) Prioritizing efficiency, then the classification accuracy cannot be guaranteed, and 2) Choosing performance and sacrificing the power consumption. Neither of these two options is optimal. Other solutions may include static mismatch error compensation or dynamically operation condition adjustment.

For example, another approach may be to focus on statically correcting the error by either adding extra correction hardware or by evolving data coding. With the aid of such hardware, designers may be able to lower the supply voltage without causing a significant negative impact on the overall neural network performance. Although error correction coding (ECC), may detect and even correct errors during data read and write in memory, the ECC cannot protect the data during computation. Hardware based error correction, on the other hand, is too complicated and difficult to implement due to basic computing element substitution requirements. Those cells need additional control and support. In addition, the corresponding layout shape and size are also different from the basic computing standard cells. There are also downsides to noise aware training: 1) mismatch between the model and the actual noise sources on-chip, 2) extra training requirements, 3) a need to conduct the training separately for different chip architectures (e.g., lacking portability when migrating networks from one design to another), etc.

Dynamically adjusting the supply voltage by continuously monitoring the classification failure rate may be another option. Based on the observed failure rate, a control system tuning the voltage regulator may enable the workload to stay at a comfortable condition. Noise aware training is another common approach to improving network tolerance to PVT. To constantly track the ambient environment, however, traditional dynamic supply voltage adjustment solutions normally are based on sensing the classification failure rate, which presents at least four technical problems: 1) The classification failure has two causes, computing fault and input corruption. There is no solution to distinguish these two by simply monitoring the classification failure rate, 2) To calculate the classification failure rate, data from data center may be required. The edge device cannot determine whether failure occurred on its own, therefore additional data transmission is required, 3) As the solution needs to wait for data and process results from the data center, the delay in the voltage control loop is unbounded, which can easily cause instability and oscillation in the loop, and 4) Voltage tuning cannot alleviate the impact of temperature and process variations. As will be discussed in greater detail, the technology described herein uses a butterfly switching based differential format in the CiM signal path to compensate for aforementioned problems without employing complicated calibration blocks.

More particularly, most CiM implementations may traditionally use single-ended signaling in their respective processing structures. As a result, these solutions suffer from a higher error rate in edge deployment, where operation conditions may change severely. By contrast, differential signals provide inherent first order cancellation of coherent noise, crosstalk, and PVT (process, voltage, and temperature) variations, which may be a common occurrence in analog, RF (radio frequency), mixed-signal, and high-speed digital links.

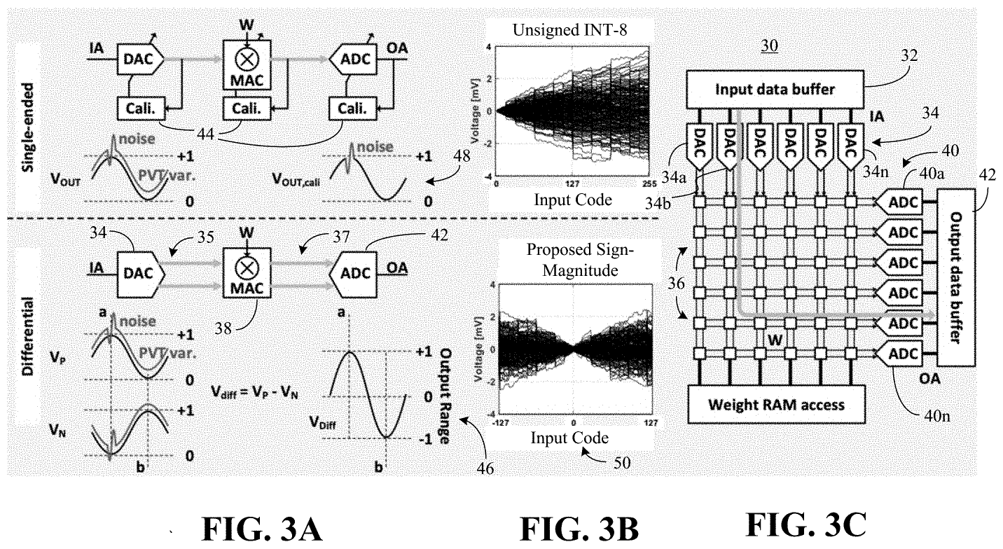

As shown in FIGS. 3A-3C, the signals transmitted, converted, processed, and computed, in an analog CiM array are in a complimentary differential pair format. Additionally, the corresponding modules on the signal path, digital to analog converter (DAC), analog MAC, and analog to digital converter (ADC), are all configured to handle differential signals.

More particularly, a CiM processor 30 includes an input data buffer 32 that provides digital activation signals (e.g., input activations/IAs) to a plurality of DACs 34 (34a-34n), which convert the digital activation signals into first analog signals 35. A symmetric differential signal path 36 uses MAC hardware 38 to conduct signed MAC operations on the first analog signals 35 and multibit weight data (e.g., “W” obtained from weight RAM accesses). In an embodiment, the multibit weight data is in a signed magnitude format. The MAC hardware 38 also outputs second analog signals 37 based on the signed MAC operations, wherein a plurality of ADCs 40 (40a-40n) convert the second analog signals 37 into digital accumulation signals (e.g., output activations/OAs). The digital accumulation signals may be sent to an output data buffer 42. In an embodiment, the DACs 34, the MAC hardware 38, and the ADCs 40 are adjusted to accept differential signals.

Of particular note is that conventional calibration modules 44 may be eliminated from the CiM processor 30 due to intrinsic PVT and noise tolerance provided by the differential signals. Additionally, the differential signals result in voltage output range 46 of the CiM processor 30 that is twice that of a conventional single-ended output range 48. Moreover, a noise profile 50 of the CiM processor 30 is symmetric around the value of zero.

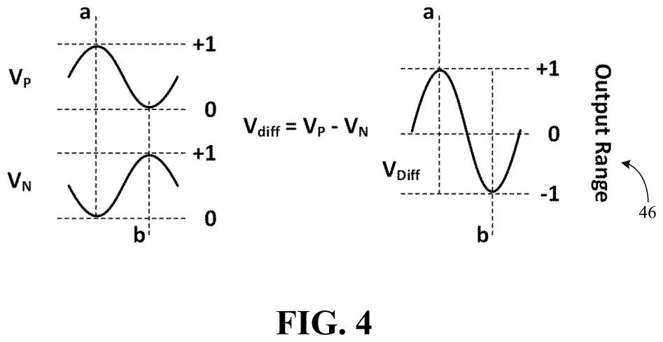

With continuing reference to FIGS. 3A and 4, the differential signaling technology described herein electrically transmits information using two complementary signals (e.g., V_{P} and V_{N}). The technique sends the same electrical signal as a differential pair of signals, each in its own conductor. Electrically, the two conductors carry voltage signals, which are equal in magnitude, but of opposite polarity. The actual signal is defined as V_{diff} (e.g., the difference between those two opposite signals). The receiving circuit responds to the difference between the two signals, which results in a signal with a magnitude that is twice as large as a single-ended signal. As a result, the signal contains an additional 6 dB (decibel) dynamic range in the limited single rail power supply. Furthermore, the scheme of two opposite polarity signals offers a straightforward way to represent positive and negative data in a single power rail circuit without introducing an additional reference voltage. The positive value is defined as when the signal V positive (V_{P}) is greater than the signal V negative (V_{N}). The support of signed data is particularly advantageous in artificial intelligence (AI) applications.

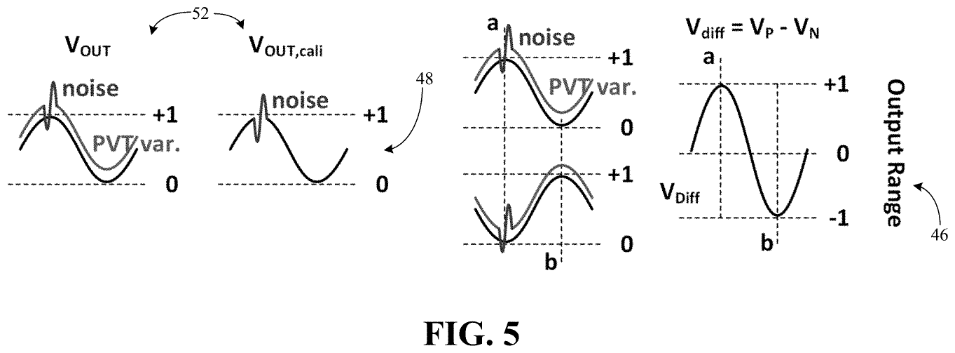

With continuing reference to FIGS. 3A and 5, in addition to the 6 dB extra headroom, differential signaling also offers automatic PVT variation and supply noise cancellation. As a balanced scheme, differential signaling shows high resistance to external disturbance due to PVT variations and coupled noise. For example, if a noise is injected to a balanced signal and the same amount (e.g., same polarity, same amplitude) of noise is added to both the positive signal and the negative signal, then when the two signals are summed, the output signal is doubled with the offset and noise being removed. In a single-ended scheme 52, however, offset due to PVT variation can be compensated by adding the calibration modules 44 (e.g., sensing the output signal), but noise cannot be removed, because noise is random and unpredictable.

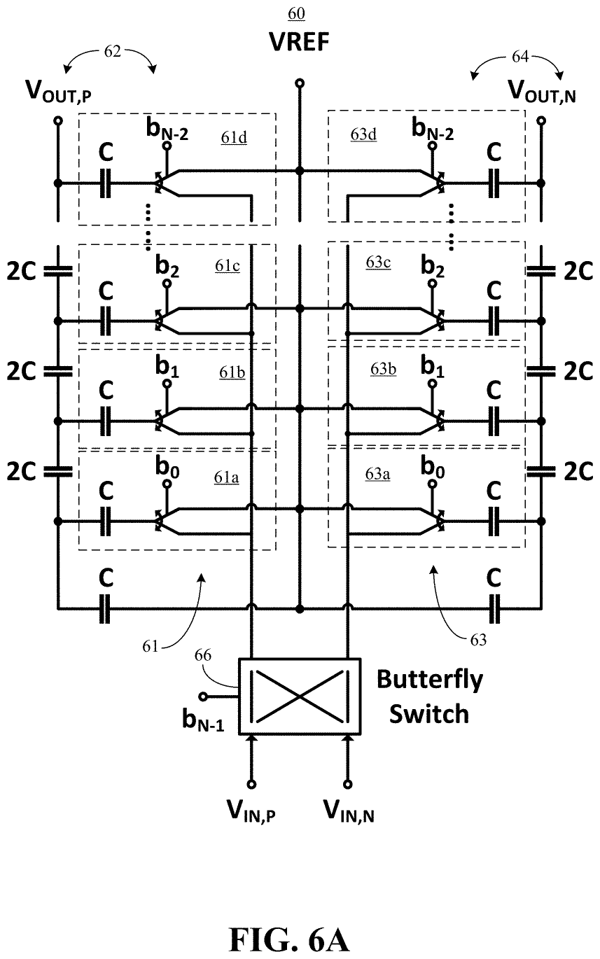

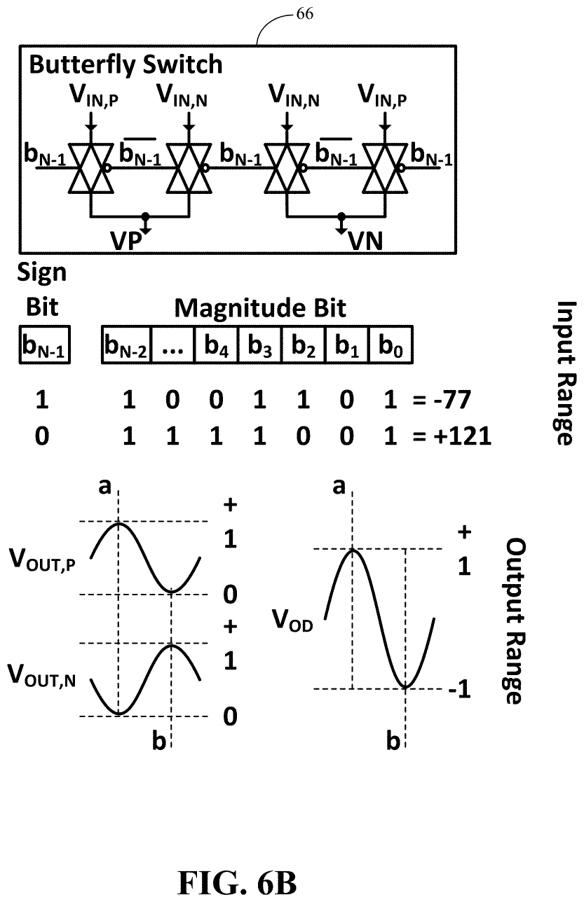

FIGS. 6A and 6B show MAC hardware 60 that may be readily incorporated into the MAC hardware 38 (FIG. 3A), already discussed. In general, butterfly switch circuitry 66 steers the second analog signals between a positive voltage (e.g., V_{OUT,P}) and a negative voltage (e.g., V_{OUT,N}) based on most significant bits (MSBs, e.g., b_{N-1}) in the multibit weight data. More particularly, a first capacitor ladder network 62 may be coupled to the butterfly switch circuitry 66, wherein the first capacitor ladder network 62 performs multiplication operations with respect to the positive voltage, and a second capacitor ladder network 64 may be coupled to the butterfly switch circuitry 66, wherein the second capacitor latter network 64 performs multiplication operations with respect to the negative voltage. In contrast with other signed implementations, the illustrated MAC hardware 60 does not require doubling the memory size, which can greatly reduce the memory write/read bandwidth.

More particularly, the two-rail capacitor ladder network 62, 64 includes two C-2C ladders placed side-by-side (e.g., implemented as passive metal-oxide-metal/MOM capacitors above a standard memory cell active region), because the differential structure uses two standalone signals to form the differential output. The two-rail ladder network 62, 64 may execute multiplication operations, and is a capacitor network in digital-to-analog converter (DAC) designs to provide analog voltage outputs. As best shown in FIG. 6A, the two-rail ladder network 62, 64 includes of a series of capacitors C segmented into branches 61 (61a-61d), 63 (63a-63d). Each branch 61, 63 contains a switch and a capacitor C that is one unit capacitance. A serial capacitor 2C with a capacitance of two unit capacitance is inserted between each of two branches 61, 63.

The switches are controlled by digital bits and connected to either a fixed reference voltage VREF or one of V_{IN,P} or V_{IN,N}. Ratioed by the serial capacitors 2C, the contributions of the branches 61, 63 are binary weighted along the two-rail ladder network 62, 64 and superimposed onto the output node of the two-rail ladder network 62, 64.

The data stored in memory cells are shared by both sides of the rail to control those switches except the MSB in the word. The MSB, assigned as the sign bit (one for negative values, zero for positive values), controls a transmission gate based butterfly switch circuitry 66 steering between the V_{IN,P} and V_{IN,N}. The GND node in the single-ended C-2C ladder is replaced by a reference node with a voltage level of half V_{IN,P} (V_{IN,P}/2). The input data is arranged in the format of “signed magnitude”, while the final output of the ladder network, V_{OD}, is formed by the difference of the V_{OUT,P} and V_{OUT,N}, in a range between −1 to +1. As a result, the equation of the differential output V_{OD} for an N-bit ladder is given below:

$${V}_{O D} = - sign ( {b}_{N - 1} ) \times {Σ}_{i = 0}^{N - 2} {b}_{i} \times \frac{1}{{2}^{N - i}}$$

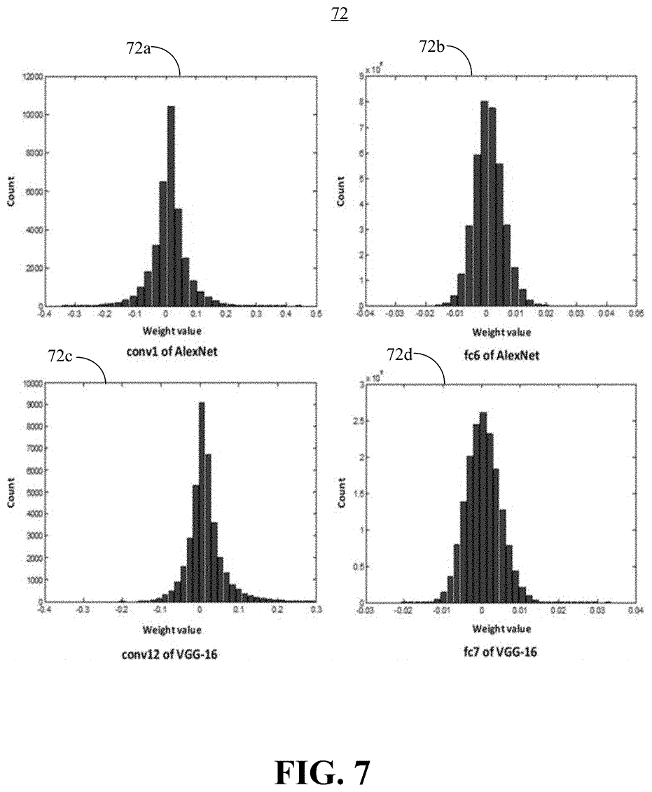

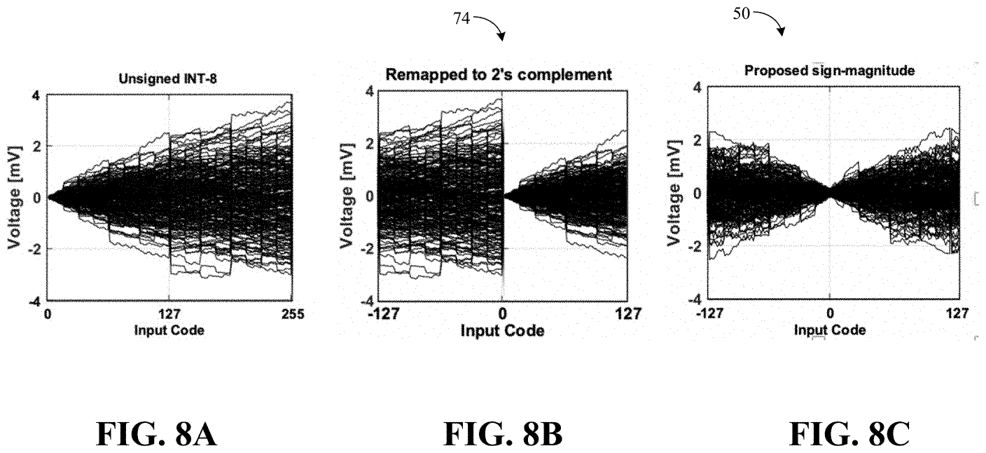

With continuing reference to FIGS. 7 and 8A-8C, as the intrinsic signed format is realized by an analog butterfly switch, a different mismatch error distribution is achieved as shown in an error profile 50 of an enhanced signed magnitude plot (e.g., error notch observed at zero). Additionally, the error distribution expands from the zero point in the center, which is perfectly aligned with the data in NNs. In a practical NN, most of the weights and the inputs are small numbers close to zero as shown in a set of weight distribution charts 72 (72a-72d, e.g., normalized in two layers—convolution layer and fully connected layer). The weight distribution is around a zero-value peak in the illustrated example. With data remapping, half of the data (e.g., negative data) suffers from larger analog errors as shown in an error profile 74 of a conventional remapped 2's complement plot. Indeed, the maximum error profile 50 of the enhanced signed magnitude plot is less than the maximum error profile 74 of the conventional remapped 2's complement plot.

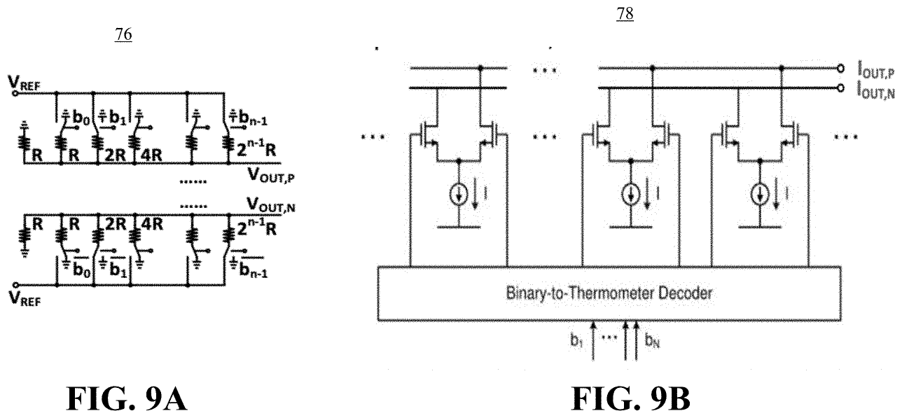

Turning now to FIGS. 9A and 9B, a multibit differential output DAC such as the DACs 34 (FIG. 3C) can achieve high common-mode rejection and reduce even-order distortion products, and is particularly advantageous for a multibit analog CiM processor. There are several approaches to implement this kind of DAC. For example, a current steering DAC 76 and/or a differential resistive DAC 78 may be used. In an embodiment, the current steering DAC 76 can support ultra high speed applications, while the differential resistive DAC 78 is easier to implement with higher linearity performance. In one example, the type of DAC 76, 78 selected is based on the speed requirement, power budget, on-chip area constraint, etc.

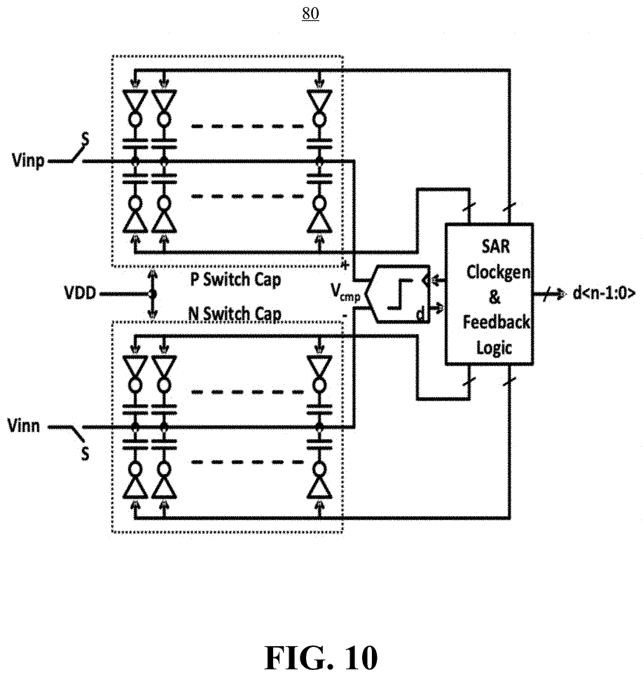

Turning now to FIG. 10, after the analog MAC operation, an ADC such as the ADCs 40 (FIG. 3C) converts the calculated analog signal back to digital data. In this regard, a successive approximation register (SAR) ADC 80 may be used for the conversion. The SAR ADC 80 is a versatile, low power, high performance option for creating an analog-to-digital conversion signal chain. Moreover, the SAR ADC 80 is relatively easy to implement. The differential SAR ADC 80 also enables the user to maximize the input range of the ADC 80. Similar to other parts, differential signaling provides the ability to double the input range for a given supply and reference setup, providing up to a 6 dB increase in dynamic range without increasing the device power consumption when compared to a single-ended or pseudo differential scheme. Additionally, the differential SAR ADC 80 eliminates the reliance on the requirement for a reference voltage, improving PVT and noise tolerance.

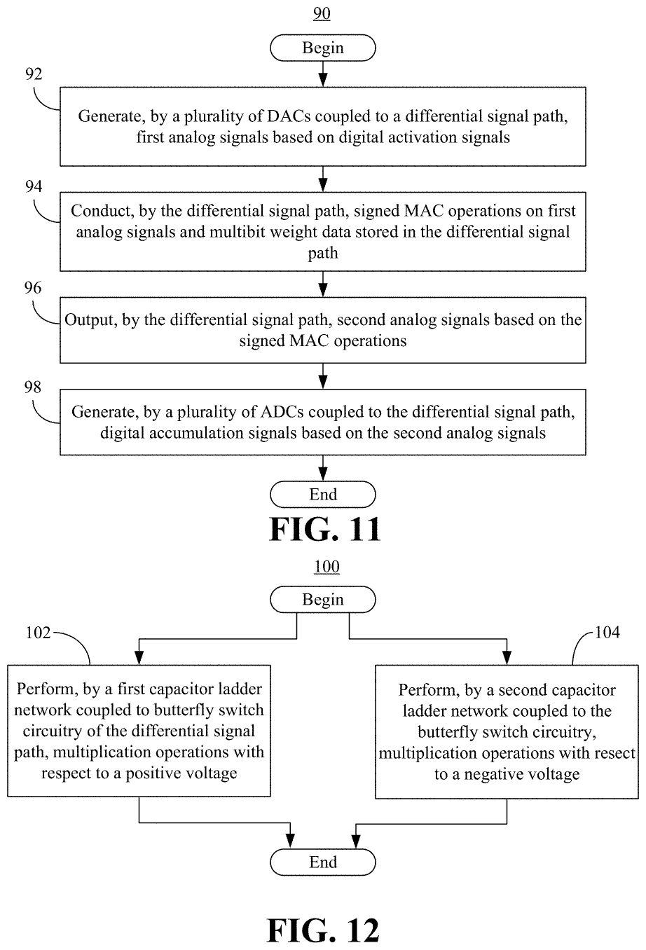

FIG. 11 shows a method 90 of operating a CiM processor. The method 90 may generally be implemented in a CiM processor such as, for example, the CiM processor 30 (FIG. 3C), already discussed. More particularly, the method 90 may be implemented as hardware in configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated processing block 92 provides for generating, by a plurality of DACs coupled to a differential signal path, first analog signals based on digital activation signals. In an embodiment, the plurality of DACs include one or more of current steering DACs or differential resistive DACs. Block 94 conducts, by the differential signal path, signed MAC operations on first analog signals and multibit weight data stored in the differential signal path. In one example, the multibit weight data is in a signed magnitude format. Moreover, block 94 may involve bypassing a remapping of the multibit weight data. Block 96 outputs, by the differential signal path, second analog signals based on the signed MAC operations. In an embodiment, block 96 also involves steering, by butterfly switch circuitry of the differential signal path, the second analog signals between a positive voltage and a negative voltage based on MSBs in the multibit weight data. Additionally, blocks 94 and 96 may bypass, by the differential signal path, a calibration of the first analog signals and the second analog signals. Block 98 generates, by a plurality of ADCs coupled to the differential signal path, digital accumulation signals based on the second analog signals. In an embodiment, the plurality of ADCs include differential SAR converters.

The method 90 therefore enhances performance at least to the extent that supporting positive/negative signals and signed multiplication with differential signals enables negative values to be represented in the analog domain (e.g., which in turn facilitates ML and NN applications). Additionally, the differential signal doubles the dynamic range of the CiM processor, which further enhances performance. Moreover, the conducting signed MAC operations in the differential signal path enables PVT robust computations and the elimination of costly calibration units. Indeed, the differential signal path provides immunity to supply noise (e.g., common mode random error), which cannot be calibrated with a single-ended signal.

FIG. 12 shows a method 100 of operating a differential signal path. The method 100 may generally be incorporated into block 94 and/or 96 (FIG. 11), already discussed. More particularly, the method 100 may be implemented as hardware in configurable logic, fixed-functionality logic, or any combination thereof.

Illustrated processing block 102 performs, by a first capacitor ladder network coupled to butterfly switch circuitry of the differential signal path, multiplication operations with respect to a positive voltage. Additionally, block 104 performs, by a second capacitor ladder network coupled to the butterfly switch circuitry, multiplication operations with respect to a negative voltage. The method 100 therefore further enhances performance at least to the extent that the first and second capacitor ladder networks obviates the need for a separate mid-rail voltage reference (e.g., enables the use of reference-less ADCs).

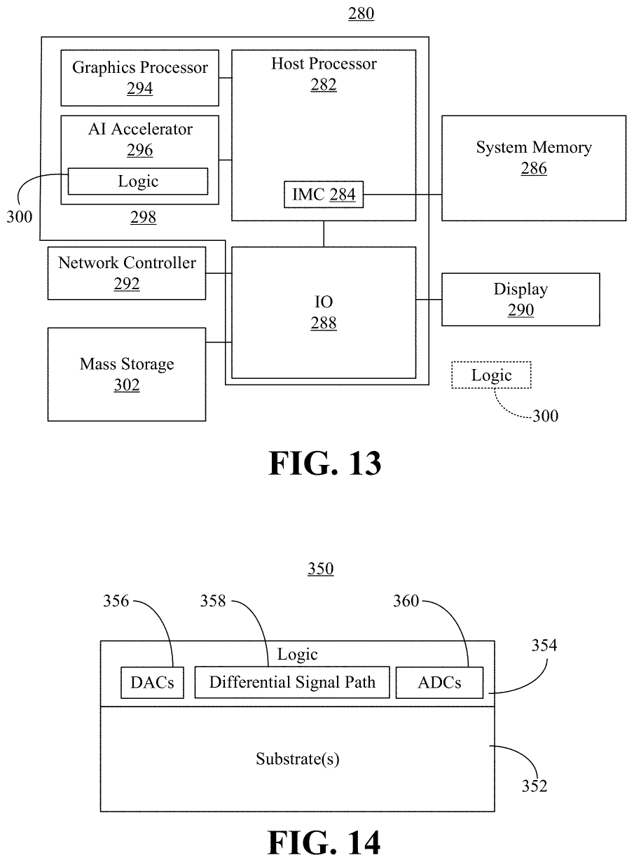

Turning now to FIG. 13, a performance-enhanced computing system 280 is shown. The system 280 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). In one example, the network controller 292 obtains an input data stream associated with an AI, ML or NN application. The host processor 282 may be combined with the IO module 288, a graphics processor 294, and an AI accelerator 296 (e.g., CiM processor) into a system on chip (SoC) 298.

In an embodiment, the AI accelerator 296 includes logic 300 having a differential signal path that performs one or more aspects of the method 90 (FIG. 11) and/or the method 100 (FIG. 12), already discussed. The logic 300 may therefore conduct signed MAC operations on first analog signals and multibit weight data stored in the differential signal path and output second analog signals based on the signed MAC operations. The computing system 280 is therefore considered performance-enhanced at least to the extent that supporting positive/negative signals and signed multiplication with differential signals enables negative values to be represented in the analog domain (e.g., which in turn facilitates ML and NN applications). Additionally, the differential signal doubles the dynamic range of the AI accelerator 296, which further enhances performance. Moreover, the conducting signed MAC operations in the differential signal path enables PVT robust computations and the elimination of costly calibration units. Indeed, the differential signal path provides immunity to supply noise (e.g., common mode random error), which cannot be calibrated with a single-ended signal.

FIG. 14 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. The logic 354 may be readily substituted for the logic 300 (FIG. 13), already discussed. In an embodiment, the logic 354 includes a plurality of DACs 356, a differential signal path 358, and a plurality of ADCs 360 and implements one or more aspects of the method 90 (FIG. 11) and/or the method 100 (FIG. 12), already discussed.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

### Additional Notes and Examples:

Example 1 includes a performance-enhanced computing system comprising a network controller and a processor coupled to the network controller, wherein the processor includes logic coupled to one or more substrates, the logic including a differential signal path to conduct signed multiply-accumulate (MAC) operations on first analog signals and multibit weight data stored in the differential signal path, and output second analog signals based on the signed MAC operations.

Example 2 includes the computing system of Example 1, wherein the multibit weight data is in a signed magnitude format.

Example 3 includes the computing system of Example 1, wherein the differential signal path includes butterfly switch circuitry to steer the second analog signals between a positive voltage and a negative voltage based on most significant bits in the multibit weight data.

Example 4 includes the computing system of Example 3, wherein the differential signal path further includes a first capacitor ladder network coupled to the butterfly switch circuitry, wherein the first capacitor ladder network is to perform multiplication operations with respect to the positive voltage, and a second capacitor ladder network coupled to the butterfly switch circuitry, wherein the second capacitor ladder network is to perform multiplication operations with respect to the negative voltage.

Example 5 includes the computing system of Example 1, wherein the differential signal path is to bypass a remapping of the multibit weight data.

Example 6 includes the computing system of Example 1, wherein the differential signal path is to bypass a calibration of the first analog signals and the second analog signals.

Example 7 includes the computing system of any one of Examples 1 to 6, wherein the logic further includes a plurality of digital to analog converters (DACs) coupled to the differential signal path, the plurality of DACs to generate the first analog signals based on digital activation signals, and wherein the plurality of DACs include one or more of current steering DACs or differential resistive DACs.

Example 8 includes the computing system of any one of Examples 1 to 7, wherein the logic further includes a plurality of analog to digital converters (ADCs) coupled to the differential signal path, the plurality of ADCs to generate digital accumulation signals based on the second analog signals, and wherein the plurality of ADCs include differential successive approximation register converters.

Example 9 includes a semiconductor apparatus comprising one or more substrates, and logic coupled to the one or more substrates, wherein the logic includes a differential signal path and is implemented at least partly in one or more of configurable or fixed-functionality hardware, the differential signal path to conduct signed multiply-accumulate (MAC) operations on first analog signals and multibit weight data stored in the differential signal path, and output second analog signals based on the signed MAC operations.

Example 10 includes the semiconductor apparatus of Example 9, wherein the multibit weight data is in a signed magnitude format.

Example 11 includes the semiconductor apparatus of Example 9, wherein the differential signal path includes butterfly switch circuitry to steer the second analog signals between a positive voltage and a negative voltage based on most significant bits in the multibit weight data.

Example 12 includes the semiconductor apparatus of Example 11, wherein the differential signal path further includes a first capacitor ladder network coupled to the butterfly switch circuitry, wherein the first capacitor ladder network is to perform multiplication operations with respect to the positive voltage, and a second capacitor ladder network coupled to the butterfly switch circuitry, wherein the second capacitor ladder network is to perform multiplication operations with respect to the negative voltage.

Example 13 includes the semiconductor apparatus of Example 9, wherein the differential signal path is to bypass a remapping of the multibit weight data.

Example 14 includes the semiconductor apparatus of Example 9, wherein the differential signal path is to bypass a calibration of the first analog signals and the second analog signals.

Example 15 includes the semiconductor apparatus of any one of Examples 9 to 14, wherein the logic further includes a plurality of digital to analog converters (DACs) coupled to the differential signal path, the plurality of DACs to generate the first analog signals based on digital activation signals, and wherein the plurality of DACs include one or more of current steering DACs or differential resistive DACs.

Example 16 includes the semiconductor apparatus of any one of Examples 9 to 15, wherein the logic further includes a plurality of analog to digital converters (ADCs) coupled to the differential signal path, the plurality of ADCs to generate digital accumulation signals based on the second analog signals, and wherein the plurality of ADCs include differential successive approximation register converters.

Example 17 includes the semiconductor apparatus of any one of Examples 9 to 15, wherein the logic coupled to the one or more substrates includes transistor channel regions that are positioned within the one or more substrates.

Example 18 includes a method of operating a compute in memory (CiM) processor, the method comprising conducting, by a differential signal path, signed multiply-accumulate (MAC) operations on first analog signals and multibit weight data stored in the differential signal path, and outputting, by the differential signal path, second analog signals based on the signed MAC operations.

Example 19 includes the method of Example 18, wherein the multibit weight data is in a signed magnitude format.

Example 20 includes the method of Example 18, further including steering, by butterfly switch circuitry of the differential signal path, the second analog signals between a positive voltage and a negative voltage based on most significant bits in the multibit weight data.

Example 21 includes the method of Example 20, further including performing, by a first capacitor ladder network coupled to the butterfly switch circuitry, multiplication operations with respect to the positive voltage, and performing, by a second capacitor ladder network coupled to the butterfly switch circuitry, multiplication operations with respect to the negative voltage.

Example 22 includes the method of Example 18, further including bypassing, by the differential signal path, a remapping of the multibit weight data.

Example 23 includes the method of Example 18, further including bypassing, by the differential signal path, a calibration of the first analog signals and the second analog signals.

Example 24 includes the method of any one of Examples 18 to 23, further including generating, by a plurality of digital to analog converters (DACs) coupled to the differential signal path, the first analog signals based on digital activation signals, wherein the plurality of DACs include one or more of current steering DACs or differential resistive DACs.

Example 25 includes the method of any one of Examples 18 to 23, further including generating, by a plurality of analog to digital converters (ADCs) coupled to the differential signal path, digital accumulation signals based on the second analog signals, wherein the plurality of ADCs include differential successive approximation register converters.

Example 26 includes an apparatus comprising means for performing the method of any one of Examples 18 to 25.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller; and
a processor coupled to the network controller, wherein the processor includes logic coupled to one or more substrates, the logic including a differential signal path to:
conduct signed multiply-accumulate (MAC) operations on first analog signals and multibit weight data stored in the differential signal path, and
output second analog signals based on the signed MAC operations.

2. The computing system of claim 1, wherein the multibit weight data is in a signed magnitude format.

3. The computing system of claim 1, wherein the differential signal path includes butterfly switch circuitry to steer the second analog signals between a positive voltage and a negative voltage based on most significant bits in the multibit weight data.

4. The computing system of claim 3, wherein the differential signal path further includes:
a first capacitor ladder network coupled to the butterfly switch circuitry, wherein the first capacitor ladder network is to perform multiplication operations with respect to the positive voltage; and
a second capacitor ladder network coupled to the butterfly switch circuitry, wherein the second capacitor ladder network is to perform multiplication operations with respect to the negative voltage.

5. The computing system of claim 1, wherein the differential signal path is to bypass a remapping of the multibit weight data.

6. The computing system of claim 1, wherein the differential signal path is to bypass a calibration of the first analog signals and the second analog signals.

7. The computing system of claim 1, wherein the logic further includes a plurality of digital to analog converters (DACs) coupled to the differential signal path, the plurality of DACs to generate the first analog signals based on digital activation signals, and wherein the plurality of DACs include one or more of current steering DACs or differential resistive DACs.

8. The computing system of claim 1, wherein the logic further includes a plurality of analog to digital converters (ADCs) coupled to the differential signal path, the plurality of ADCs to generate digital accumulation signals based on the second analog signals, and wherein the plurality of ADCs include differential successive approximation register converters.

9. A semiconductor apparatus comprising:
one or more substrates; and
logic coupled to the one or more substrates, wherein the logic includes a differential signal path and is implemented at least partly in one or more of configurable or fixed-functionality hardware, the differential signal path to:
conduct signed multiply-accumulate (MAC) operations on first analog signals and multibit weight data stored in the differential signal path; and
output second analog signals based on the signed MAC operations.

10. The semiconductor apparatus of claim 9, wherein the multibit weight data is in a signed magnitude format.

11. The semiconductor apparatus of claim 9, wherein the differential signal path includes butterfly switch circuitry to steer the second analog signals between a positive voltage and a negative voltage based on most significant bits in the multibit weight data.

12. The semiconductor apparatus of claim 11, wherein the differential signal path further includes:
a first capacitor ladder network coupled to the butterfly switch circuitry, wherein the first capacitor ladder network is to perform multiplication operations with respect to the positive voltage; and
a second capacitor ladder network coupled to the butterfly switch circuitry, wherein the second capacitor ladder network is to perform multiplication operations with respect to the negative voltage.

13. The semiconductor apparatus of claim 9, wherein the differential signal path is to bypass a remapping of the multibit weight data.

14. The semiconductor apparatus of claim 9, wherein the differential signal path is to bypass a calibration of the first analog signals and the second analog signals.

15. The semiconductor apparatus of claim 9, wherein the logic further includes a plurality of digital to analog converters (DACs) coupled to the differential signal path, the plurality of DACs to generate the first analog signals based on digital activation signals, and wherein the plurality of DACs include one or more of current steering DACs or differential resistive DACs.

16. The semiconductor apparatus of claim 9, wherein the logic further includes a plurality of analog to digital converters (ADCs) coupled to the differential signal path, the plurality of ADCs to generate digital accumulation signals based on the second analog signals, and wherein the plurality of ADCs include differential successive approximation register converters.

17. The semiconductor apparatus of claim 9, wherein the logic coupled to the one or more substrates includes transistor channel regions that are positioned within the one or more substrates.

18. A method comprising:
conducting, by a differential signal path, signed multiply-accumulate (MAC) operations on first analog signals and multibit weight data stored in the differential signal path; and
outputting, by the differential signal path, second analog signals based on the signed MAC operations.

19. The method of claim 18, wherein the multibit weight data is in a signed magnitude format.

20. The method of claim 18, further including steering, by butterfly switch circuitry of the differential signal path, the second analog signals between a positive voltage and a negative voltage based on most significant bits in the multibit weight data.

21. The method of claim 20, further including:
performing, by a first capacitor ladder network coupled to the butterfly switch circuitry, multiplication operations with respect to the positive voltage; and
performing, by a second capacitor ladder network coupled to the butterfly switch circuitry, multiplication operations with respect to the negative voltage.

22. The method of claim 18, further including bypassing, by the differential signal path, a remapping of the multibit weight data.

23. The method of claim 18, further including bypassing, by the differential signal path, a calibration of the first analog signals and the second analog signals.

24. The method of claim 18, further including generating, by a plurality of digital to analog converters (DACs) coupled to the differential signal path, the first analog signals based on digital activation signals, wherein the plurality of DACs include one or more of current steering DACs or differential resistive DACs.

25. The method of claim 18, further including generating, by a plurality of analog to digital converters (ADCs) coupled to the differential signal path, digital accumulation signals based on the second analog signals, wherein the plurality of ADCs include differential successive approximation register converters.
